(19) United States
(12) Patent Application Publication
(10) Pub. No.: US 2026/0164864 A1
(43) Pub. Date: Jun. 11, 2026

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: XIUSHAN ZHU, Xiamen (CN); QI JING, Xiamen (CN); YAN LI, Xiamen (CN); Chunhsien LEE, Xiamen (CN); Juchin TU, Xiamen (CN); Chung-Ying CHANG, Xiamen (CN)

(21) Appl. No.: 19/405,487

(22) Filed: Dec. 2, 2025

(30) Foreign Application Priority Data
Dec. 5, 2024 (CN) 202411780361.2

(51) Int. Cl. H10H 20/831

(52) U.S. Cl. CPC H10H 20/8316

(57) ABSTRACT

An LED includes a substrate, a semiconductor stacked layer disposed on the substrate, first and second connecting electrodes electrically connected to first and second semiconductor layers respectively, and first and second pad electrodes disposed on the first and second semiconductor layers and electrically connected to the first and second connecting electrodes respectively. A projection of the second pad electrode in a second direction does not overlap with a projection of the first connecting electrode in the second direction. Since there is no first connecting electrode present at the edge and the inner surrounding area of the second pad electrode, only a P-polarity chip structure exists below a P-polarity pad electrode, which would not cause current leakage of the LED resulting from substrate material protrusion or insulating layer rupture during thermocompression in a packaging process, and thus it is suitable for the thermocompression die bonding process, ensuring product quality.

### CROSS-REFERENCE TO RELATED APPLICATION

This application claims priority to Chinese Patent Application No. 202411780361.2, filed on Dec. 5, 2024, which is herein incorporated by reference in its entirety.

### TECHNICAL FIELD

The disclosure relates to the technical field of semiconductor manufacturing technologies, and more particularly to a light-emitting diode (LED) and a light-emitting device.

### BACKGROUND

An LED is a semiconductor device whose basic structure includes a PN junction between a P-type semiconductor and an N-type semiconductor. When a forward voltage is applied to the LED, electrons and holes recombine at the PN junction, thereby releasing energy. This energy is emitted in the form of photons to produce optical radiation.

Existing LED structures are classified into two categories: a non P/N separation and planarization design and a P/N separation and planarization design. The former design is not suitable for thermocompression die bonding due to the presence of uneven film layers in an electrode region, which would cause pressure during the thermocompression die boding process to fracture an insulating layer (also referred to as a passivation layer (PV)) in non-planar regions. The latter P/N separation and planarization design suffers from damage to the product structure caused by the substrate material during packaging due to the presence of N-side connecting electrode at the side edge of and/or underneath the P-side pad electrode. Consequently, both the designs suffer from a certain risk of current leakage in the packaging process, affecting product service life and yield. Therefore, it is necessary to provide a technical solution to solve or improve the above problems.

### SUMMARY

In view of drawbacks and deficiencies of existing LED chips mentioned above, the disclosure provides an LED and a light-emitting device to effectively improve the process quality of a chip during thermocompression die bonding, thereby increasing product yield and service life.

To achieve the above purposes and other related purposes, the disclosure provides an LED, which includes a substrate, a semiconductor stacked layer, a first connecting electrode, a second connecting electrode, a first pad electrode, and a second pad electrode.

The substrate has a first side, a second side, a third side, and a fourth side sequentially connected in that order. The first side is connected to the fourth side. The second side and the fourth side each extends along a first direction, and the first side and the third side each extends along a second direction. The first direction and the second direction are perpendicular to each other.

The semiconductor stacked layer is disposed on the substrate. The semiconductor stacked layer includes a first semiconductor layer, a second semiconductor layer, and an active layer disposed between the first semiconductor layer and the second semiconductor layer.

The first connecting electrode and the second connecting electrode are disposed on the semiconductor stacked layer, and the first connecting electrode and the second connecting electrode are electrically connected to the first semiconductor layer and the second semiconductor layer, respectively.

The first pad electrode and the second pad electrode are disposed on the first semiconductor layer and the second semiconductor layer, and the first pad electrode and the second pad electrode are electrically connected to the first connecting electrode and the second connecting electrode, respectively.

The first connecting electrode and the first pad electrode are arranged close to the third side of the substrate, and the second connecting electrode and the second pad electrode are arranged close to the first side of the substrate.

A projection of the second pad electrode in the second direction does not overlap with a projection of the first connecting electrode in the second direction.

The disclosure further provides a light-emitting device, which includes a package substrate and at least one LED. The at least one LED is disposed on a surface of the package substrate, and the package substrate is electrically connected to an electrode structure of each of the at least one LED. Each of the at least one LED is the LED as described above.

Compared with the related art, the LED and the light-emitting device provided by the disclosure may at least achieve the following beneficial effects.

The LED of the disclosure optimizes the structure and distribution of P/N electrodes. A P/N electrode separation design is employed, and there is no first connecting electrode present at the edge and the inner surrounding area of the second pad electrode. Furthermore, only a P-polarity chip structure exists below a P-polarity pad electrode. This configuration would not cause current leakage of the LED resulting from substrate material protrusion or insulating layer rupture during thermocompression in a packaging process, and thus it is suitable for the thermocompression die bonding process, ensuring product quality.

In addition, the light-emitting device provided by the disclosure includes the LED described above. Therefore, the light-emitting device also achieves the beneficial effects mentioned above.

### BRIEF DESCRIPTION OF DRAWINGS

FIG. 1 illustrates a schematic diagram of a planar structure of an LED in the related art.

FIG. 2 illustrates a schematic cross-sectional view of the LED shown in FIG. 1 taken along the section line A-A'.

FIG. 3 illustrates a scanning electron microscope (SEM) image of structural defects generated during die bonding of the LED in the related art.

FIG. 4 illustrates a schematic diagram of a planar structure of an LED provided by the disclosure.

FIGS. 5A-5H illustrate schematic diagrams of a manufacturing process of the LED provided by the disclosure.

FIG. 6 illustrate a schematic cross-section view of the LED shown in FIG. 4 taken along the section line B-B'.

FIG. 7 illustrates a schematic enlarged view of the region I shown in FIG. 4.

FIG. 8 illustrates a schematic structural diagram of a light-emitting device provided by the disclosure.

DESCRIPTION OF REFERENCE SIGNS
10—substrate; 20—semiconductor stacked layer; 201—first semiconductor layer; 202—active layer; 203—second semiconductor layer; 204—semiconductor mesa; 205—peripheral portion; 205a—first outer sidewall; 205b—second outer sidewall; 206—through-hole; 30—transparent conductive layer; 30a—third outer sidewall; 40—current-blocking layer; 50—reflective layer; 50a—outer edge; 60—first insulating layer; 71—first connecting electrode; 711—first edge; 711a—first-edge first portion; 711b—first-edge second portion; 711c—first-edge third portion; 711d—first-edge fourth portion; 712—first transition segment; 72—second connecting electrode; 721—second edge; 721a—second-edge first portion; 721b—second-edge second portion; 721c—second-edge third portion; 721d—second-edge fourth portion; 722—second transition segment; 80—second insulating layer; 91—first pad electrode; 92—second pad electrode; E1—first side; E2—second side; E3—third side; E4—fourth side; OP1—first opening; OP2—second opening; OP3—third opening; OP4—fourth opening; OP5—fifth opening; 101—package substrate; 102—light-emitting element.

### DETAILED DESCRIPTION OF EMBODIMENTS

The following specific embodiments illustrate the implementation of the disclosure, and those skilled in the art can easily understand other advantages and effects of the disclosure from the content disclosed in the disclosure. The disclosure can also be implemented or applied through different specific implementation methods, and various details in the disclosure can be modified or changed based on different perspectives and applications without departing from the spirit of the disclosure. It should be noted that, without conflict, the following embodiments and their features can be combined with each other.

It should be noted that attached drawings provided in the embodiments of the disclosure are only schematic illustrations of basic concepts of the disclosure. Although they show only components relevant to the disclosure and are not drawn to an exact number, shape, or size of the components as implemented in practice, the actual implementation may vary freely in terms of component form, quantity, and proportion, and the layout of the components may also be more complex. Structures, proportions, sizes, and other aspects depicted in the attached drawings of the disclosure are provided solely to facilitate understanding and reading by those skilled in the art, and are not intended to limit the conditions under which the disclosure may be implemented. Therefore, they do not have substantive technical significance. Any modification of the structure, change in proportional relationship, or adjustment in size, as long as it does not affect the efficacy and purposes achievable by the disclosure, shall still fall within the scope of the technical content disclosed in the disclosure.

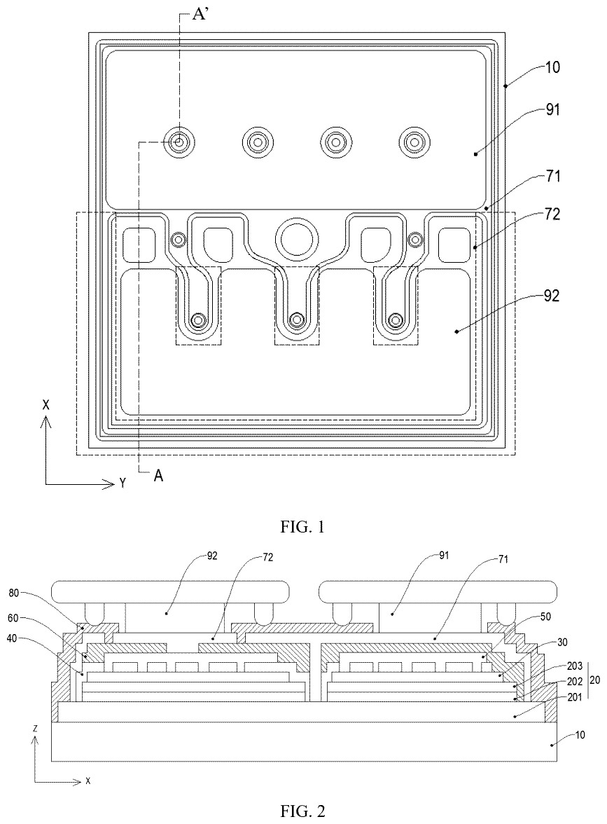

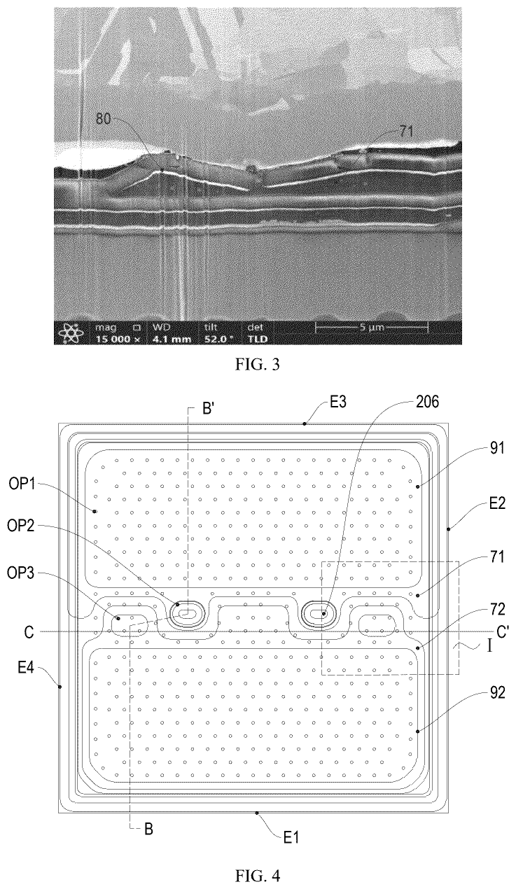

FIG. 1 illustrates a schematic diagram of a planar structure of an LED in the related art; FIG. 2 illustrates a schematic cross-sectional view of the LED shown in FIG. 1 taken along the section line A-A′; and FIG. 3 illustrates a SEM image of structural defects generated during die bonding of the LED in the related art. As shown in FIGS. 1-3, although a P/N separation and planarization design can, to a certain extent, prevent current leakage caused by crushing an insulating layer in non-planar regions during thermocompression die bonding, metal structures of a first connecting electrode still remain at lateral edges and inside a second pad electrode (see dashed boxes). During thermocompression die bonding, the presence of the first connecting electrode at the side of the second pad electrode can lead to undesirable phenomena such as current leakage of the LED caused by substrate material (e.g., nickel (Ni)) protrusion or impacts during a packaging process, which affects the product service life and yield. Based on the background and the above-mentioned technical deficiencies, the disclosure provides an LED and a light emitting device to effectively solve or mitigate the above-mentioned technical problems. The following provides a detailed description of the technical solution of the disclosure through embodiments.

For ease of description, in a coordinate system of each attached drawing, an X-axis is defined as a first direction, a Y-axis is defined as a second direction, and a Z-axis is defined as a third direction.

As shown in FIGS. 4-7, an embodiment of the disclosure provides an LED, which includes a substrate 10 and a semiconductor stacked layer 20.

The substrate 10 has an upper surface and further has a first side E1, a second side E2, a third side E3, and a fourth side E4. The first side E1, the second side E2, the third side E3, and the fourth side E4 are sequentially connected in that order. The first side E1 is connected to the second side E2. The first side E1 and the third side E3 each extends along the second direction, and the second side E2 and the fourth side E4 each extends along the first direction. The first direction and the second direction are perpendicular to each other.

In a specific embodiment, the substrate 10 can be formed from a carrier wafer suitable for growth of semiconductor materials. Moreover, the substrate 10 can be formed of a material with high thermal conductivity, or can be a conductive substrate or an insulating substrate. In addition, the substrate 10 can be formed of a transparent material that provides sufficient mechanical strength to prevent the semiconductor stacked layer 20 from warping and to enable efficient chip separation via scribing and breaking processes. For example, the substrate 10 can be a sapphire (also referred to as aluminum oxide (Al₂O₃)) substrate, a silicon carbide (SiC) substrate, a silicon (Si) substrate, a zinc oxide (ZnO) substrate, a gallium nitride (GaN) substrate, a gallium arsenide (GaAs) substrate, or a gallium phosphide (GaP) substrate. In the embodiment, the substrate 10 is a surface-patterned sapphire substrate having protrusions formed, for instance, by dry etching without a fixed slope or by wet etching with a defined slope.

The semiconductor stacked layer 20 is disposed on the upper surface of the substrate 10. The semiconductor stacked layer 20 includes a first semiconductor layer 201, a second semiconductor layer 203, and an active layer 202 disposed between the first semiconductor layer 201 and the second semiconductor layer 203. The first semiconductor layer 201, the active layer 202, and the second semiconductor layer 203 are sequentially stacked in that order along the third direction. Furthermore, the semiconductor stacked layer 20 includes a peripheral portion 205 and a semiconductor mesa 204. The peripheral portion 205 is formed by removing the second semiconductor layer 203, the active layer 202, and a portion of the first semiconductor layer 201 through a method such as etching, and the peripheral portion 205 surrounds the semiconductor mesa 204. The peripheral portion 205 has a first outer sidewall 205a connected to the substrate 10, and the semiconductor mesa 204 includes a second outer sidewall 205b connected to the peripheral portion 205.

In a specific embodiment, the semiconductor stacked layer 20 is formed on the substrate 10 by a method such as metal-organic chemical vapor deposition (MOCVD), molecular-beam epitaxy (MBE), hydride vapor phase epitaxy (HVPE), physical vapor deposition (PVD), or ion plating. The first semiconductor layer 201, the active layer 202, and the second semiconductor layer 203 each may be formed of at least one from Group III-nitride compound semiconductor materials such as GaN, aluminum nitride (AlN), indium gallium nitride (InGaN), aluminum gallium nitride (AlGaN), or indium aluminum gallium nitride (InAlGaN). The first semiconductor layer 201 is an electron-supplying layer, which may be formed by doping with an n-type dopant such as Si, germanium (Ge), selenium (Se), tellurium (Te), or carbon (C). The second semiconductor layer 203 is a hole-supplying layer, which may be formed by doping with a p-type dopant such as magnesium (Mg), zinc (Zn), beryllium (Be), calcium (Ca), strontium (Sr), or barium (Ba). The active layer 202 is a layer in which electrons supplied from the first semiconductor layer 201 and holes supplied from the second semiconductor layer 203 recombine to emit light of a predetermined wavelength. The active layer 202 may be formed as a multi-layer semiconductor thin film having a single or multiple quantum well structure formed by alternately stacked well layers and barrier layers. A material composition or a stoichiometric ratio of the active layer 202 is selected according to the desired output light wavelength. The active layer 202 may be made of at least one selected from group III-V compound semiconductor materials such as InGaN/GaN, InGaN/InGaN, GaN/AlGaN, InAlGaN/GaN, gallium arsenide (indium gallium arsenide)/aluminum gallium arsenide (GaAs(InGaAs)/AlGaAs), and Gallium phosphide (indium gallium phosphide)/aluminum gallium phosphideb(GaP(InGaP)/AlGaP).

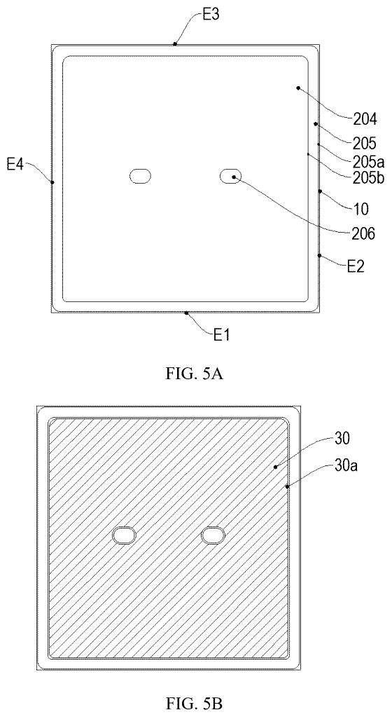

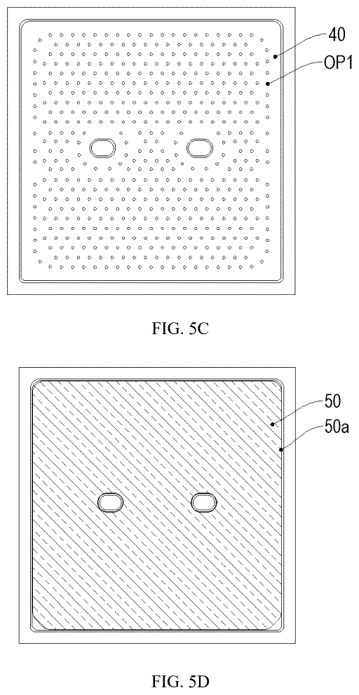

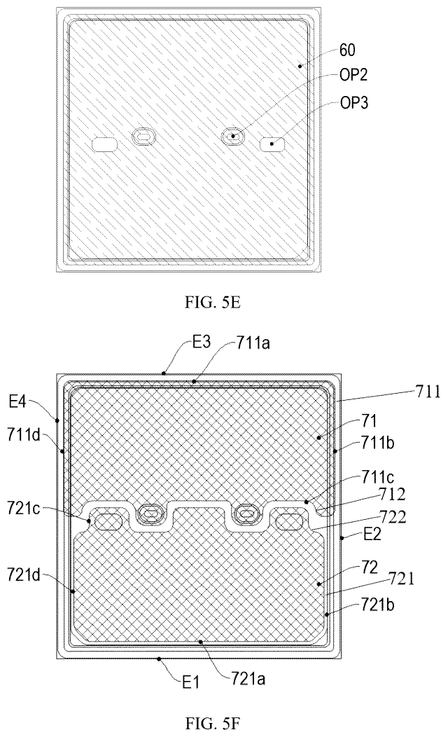

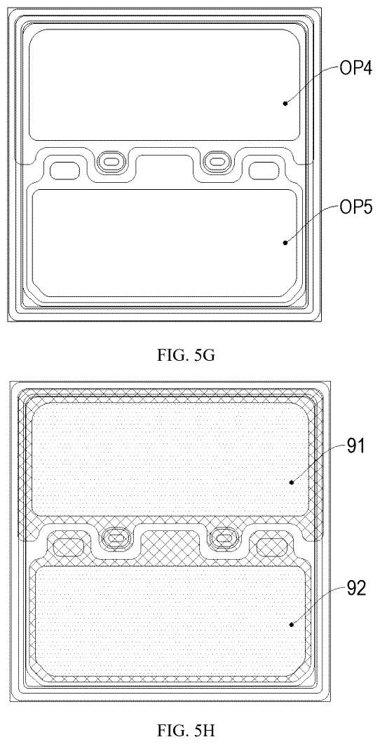

As shown in FIG. 4 and FIGS. 5A-5H, FIGS. 5A-5H illustrate schematic diagrams of a manufacturing process of the LED provided by the disclosure.

First, the semiconductor stacked layer 20 is patterned by a method such as photolithography or etching to form the semiconductor mesa 204, the peripheral portion 205, and through-holes 206. By removing portions of the second semiconductor layer 203 and the active layer 202, portions of a surface of the first semiconductor layer 201 are exposed to form the peripheral portion 205 and the through-holes 206, respectively. The through-holes 206 can be distributed on the semiconductor stacked layer 20 in a regular array. It should be understood that the arrangement and number of the through-holes 206 can be varied in various ways. Exposed regions of the first semiconductor layer 201 are not limited to shapes that match the through-holes 206. For example, the exposed regions of the first semiconductor layer 201 may be linear, or may combine holes and lines, so that downstream customers can readily distinguish a first pad electrode 91 from a second pad electrode 92.

With continued reference to FIGS. 4 and 5, a transparent conductive layer 30 is formed on the semiconductor mesa 204. A material of the transparent conductive layer 30 may be at least one selected from the group consisting of indium tin oxide (ITO), indium oxide (InO), tin oxide (SnO), cadmium tin oxide (CTO), antimony tin oxide (ATO), ZnO, and GaP. The transparent conductive layer 30 can be deposited on the semiconductor mesa 204 by a method such as PVD or chemical vapor deposition (CVD), and the transparent conductive layer 30 is in contact with the second semiconductor layer 203. In a specific embodiment, a thickness of the transparent conductive layer 30 is in a range of 5 nanometers (nm) to 100 nm. In a specific embodiment, the transparent conductive layer 30 has a third outer sidewall 30a located within a range of the semiconductor mesa 204 and has a distance from a side of the first outer sidewall 205a of the semiconductor stacked layer 20 facing away from an edge of the substrate 10, and this distance is in a range of 0 to 3 micrometers (μm).

With continued reference to FIGS. 4 and 5, a current-blocking layer 40 is formed on the transparent conductive layer 30 by a method such as PVD or CVD, and is subsequently patterned by photolithography and etching. The current-blocking layer 40 may include one or more first openings OP1 to expose a surface of the transparent conductive layer 30. The current-blocking layer 40 can cover part of the surface of the transparent conductive layer 30, part of the surface of the second semiconductor layer 203, the first outer sidewall 205a, and part of the surface of the first semiconductor layer 201. In a specific embodiment, the current-blocking layer 40 includes at least one material selected from the group consisting of silicon dioxide (SiO₂), silicon nitride (SiN), silicon oxynitride (SiOₓN_{y}), titanium dioxide (TiO₂), trisilicon tetranitride (Si₃N₄), aluminum oxide (Al₂O₃), titanium nitride (TiN), aluminum nitride (AlN), zirconium dioxide (ZrO₂), titanium aluminum nitride (TiAlN), titanium silicon nitride (TiSiN), hafnium oxide (HfO), tantalum oxide (TaO₂) and magnesium fluoride (MgF₂). In a specific embodiment, the current-blocking layer 40 may have a multilayer film structure in which insulating films with different refractive indices are alternately stacked. The multilayer film structure includes a distributed Bragg reflector (DBR) structure formed by alternately stacking a first insulating film having a first refractive index and a second insulating film having a second refractive index. In a specific embodiment, the current-blocking layer 40 may also be made of a material having a refractive index less than a refractive index of the second semiconductor layer 203. The current-blocking layer 40, together with a reflective layer 50 disposed on the current-blocking layer 40, may constitute an omnidirectional reflector (ODR) to improve the light extraction efficiency of the product. Furthermore, a thickness of the current-blocking layer 40 is specifically in a range of 200 nm to 1,500 nm. When the thickness of the current-blocking layer 40 is less than 200 nm, it cannot effectively block current, leading to current crowding and reduced light-extraction efficiency. When the thickness of the current-blocking layer 40 is greater than 1,500 nm, it may enhance light scattering and absorption, thereby reducing the light output power of the LED.

With continued reference to FIGS. 4 and 5, the reflective layer 50 is formed on the current-blocking layer 40 and makes contact with the transparent conductive layer 30 through the first openings OP1 of the current-blocking layer 40. An outer edge 50a of the reflective layer 50 may be located inside, outside, or aligned with the third outer sidewall 30a of the transparent conductive layer 30.

To effectively reduce the risk of short circuit in the LED caused by rupture of the current-blocking layer 40 while simultaneously meeting the requirements for light reflection, the reflective layer 50 should have an appropriate area. The outer edge 50a of the reflective layer 50 and a side of the first outer sidewall 205a of the semiconductor stacked layer 20 facing away from a surface of the substrate 10 have a distance, and this distance is in a range of 0 to 3 μm. Furthermore, a projection of the reflective layer 50 in the third direction is located within a projection of the second semiconductor layer 203 in the third direction, and an area of a projection of the transparent conductive layer 30 in the third direction is greater than an area of the projection of the reflective layer 50 in the third direction. In other words, a contact area between the semiconductor mesa 204 and the transparent conductive layer 30 is maximized as much as possible to lower operating voltage.

In a specific embodiment, the reflective layer 50 may be formed as a single-layer structure or a multilayer structure by using a conductive material having an ohmic characteristic with the transparent conductive layer 30. The reflective layer 50 may be made of one or more materials selected from the group consisting of gold (Au), tungsten (W), platinum (Pt), iridium (Ir), silver (Ag), aluminum (Al), copper (Cu), Ni, titanium (Ti), chromium (Cr), and alloys thereof.

In a specific embodiment, four corners of the reflective layer 50 at least have two different chamfer structures configured to identify a polarity direction of the LED. By way of example, two corners of the reflective layer 50 close to corners of the substrate 10 on a P-side semiconductor are provided with a same chamfer shape, thereby distinguishing them from two corners associated with an N-side semiconductor. It will be understood that the corresponding corner structures of the P-side and N-side semiconductors on the reflective layer 50 are arranged in the same manner, and no further description is given here.

With continued reference to FIGS. 4 and 5, a first insulating layer 60 is formed on the semiconductor mesa 204 by a method such as PVD or CVD, and is subsequentially patterned by photolithography and etching. Portions of the current-blocking layer 40 covering the through-holes 206 are etched and removed to form second openings OP2, thereby exposing portions of the surface of the first semiconductor layer 201. The first insulating layer 60 further defines third openings OP3 to expose portions of a surface of the reflective layer 50. A material of the first insulating layer 60 may be essentially the same as or different from the material of the current-blocking layer 40. For example, the first insulating layer 60 may be a single-layer insulating material layer or a DBR structure to reflect light of specific wavelengths.

With continued reference to FIGS. 4 and 5, a first connecting electrode 71 and a second connecting electrode 72 are formed on the semiconductor stacked layer 20 by a method such as PVD or magnetron sputtering. The first connecting electrode 71 fills the through-holes 206 and covers the second openings OP2 to make contact with the first semiconductor layer 201, and extends to cover portions of a surface of the first insulating layer 60. The first connecting electrode 71 is insulated from the second semiconductor layer 203 by the first insulating layer 60. The second connecting electrode 72 covers the third openings OP3 to make contact with portions of the reflective layer 50, and extends to cover portions of the surface of the first insulating layer 60. The second connecting electrode 72 is electrically connected to the second semiconductor layer 203 through the reflective layer 50. A projection of the second connecting electrode 72 is no-overlapped with a projection of each through-holes 206 in a direction perpendicular to the semiconductor stacked layer 20.

In a specific embodiment, the first connecting electrode 71 has a first edge 711, and the first edge 711 includes a first-edge first portion 711a facing towards the third side E3 of the substrate 10, a first-edge second portion 711b facing towards the second side E2 of the substrate 10, a first-edge third portion 711c facing towards the second connecting electrode 72, and a first-edge fourth portion 711d facing towards the fourth side E4 of the substrate 10. The second connecting electrode 72 has a second edge 721, and the second edge 721 includes a second-edge first portion 721a facing towards the first side E1 of the substrate 10, a second-edge second portion 721b facing towards the second side E2 of the substrate 10, a second-edge third portion 721c facing towards the first connecting electrode 71, and a second-edge fourth portion 721d facing towards the fourth side E4 of the substrate 10.

In a specific embodiment, the first-edge third portion 711c of the first connecting electrode 71 and the second-edge third portion 721c of the second connecting electrode 72 are spaced apart by a distance, so that the first connecting electrode 71 does not contact the second connecting electrode 72, and the first connecting electrode 71 is electrically isolated from the second connecting electrode 72 by a portion of the first insulating layer 60. A projection of the first-edge first portion 711a in the first direction and a projection of the second-edge first portion 721a in the first direction have an overlapping region. Furthermore, since the first connecting electrode 71 extends over the semiconductor mesa 204 through the through-holes 206, and the second connecting electrode 72 extends over the semiconductor mesa 204 while avoiding the through-holes 206, a projection of the first-edge third portion 711 c in the second direction and a projection of the second-edge third portion 721c in the second direction have an overlapping region, thereby optimizing current spreading performance. Projections of the other three edges of the first connecting electrode 71 does not overlap with projections of the other three edges of the second connecting electrode 72 in the second direction, respectively. That is, a periphery of the P-side semiconductor layer is not surrounded or partially surrounded by the first connecting electrode 71, thereby avoiding current leakage caused by damage to structure during die bonding.

Referring to FIG. 4, the chip is divided into upper and lower regions in the third direction by a line C-C′, which coincides with a center line of the chip. It is to be understood that the upper region is the N-side and the lower region is the P-side. In a specific embodiment, the through-holes 206 are all located above the center line, and the first connecting electrode 71 is also located above the center line.

The technical solution provided by the disclosure, in which the first connecting electrode 71 does not overlap with the second pad electrode 92, is suitable for chips with low current density. If the current density is too high, the current spreading effect may be compromised. The technical solution of the disclosure is typically applicable to chips with a current density of less than 0.6 amperes per square millimeter (A/mm²).

In a specific embodiment, to improve current spreading performance of the LED, the first connecting electrode 71 is extended through the distribution of the through-holes 206, so that an area of the first connecting electrode 71 is greater than an area of the second connecting electrode 72. Furthermore, a ratio of the area of the first connecting electrode 71 to the area of the second connecting electrode 72 is in a range of 1.00 to 1.30.

In a specific embodiment, the first connecting electrode 71 has an edge close to an edge of the substrate 10, and a projection of the edge of the first connecting electrode 71 in the third direction is located within a projection of the semiconductor mesa 204 in the third direction. Specifically, projections of the first-edge first portion 711a, the first-edge second portion 711b, and the first-edge fourth portion 711d of the first connecting electrode 71 in the third direction are all located within the projection of the semiconductor mesa 204 in the third direction. That is, neither the edge of the first connecting electrode 71 nor the edge of the second connecting electrode 72 is in contact with the peripheral portion 205 of the first semiconductor layer 201.

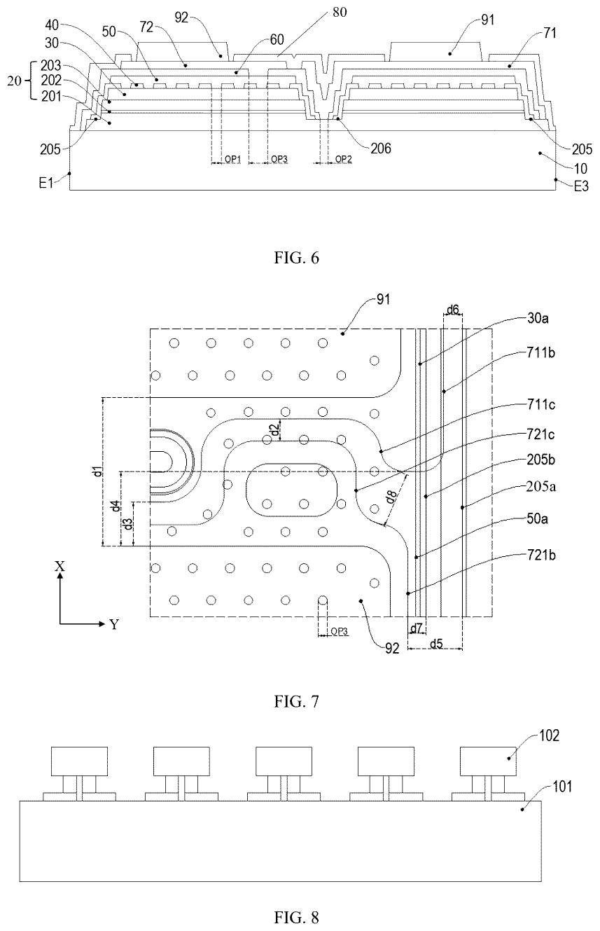

In a specific embodiment, and as shown in FIG. 6, the first connecting electrode 71 has an edge close to an edge of the substrate 10. A projection of the edge of the first connecting electrode 71 in the third direction is located outside a projection of the semiconductor mesa 204 in the third direction but inside a projection of the peripheral portion 205 in the third direction. Specifically, at least one of the first-edge first portion 711a, the first-edge second portion 711b, or the first-edge fourth portion 711d of the first connecting electrode 71 extends onto the peripheral portion 205 and makes contact with the first semiconductor layer 201 to enhance current spreading performance. The second connecting electrode 72 is formed on the semiconductor mesa 204 and does not extend onto the peripheral portion 205. Furthermore, a projection of the second connecting electrode 72 in the first direction is located within a projection of the first connecting electrode 71 in the first direction. The first connecting electrode 71 and the first outer sidewall 205 a have a minimum distance d6, and d6 is in a range of 0 to 20μm, thereby maximizing the area of the second connection electrode 72 as much as possible. Consequently, the second pad electrode 92 can also be correspondingly enlarged, which is advantageous for improving heat dissipation of the LED and enhancing the die-shear strength of the LED. By way of example, d6 may be in a range of 0 to 1 μm, 0 to 5 μm, 0 to 10 μm, or 0 to 18 μm.

In a specific embodiment, the first-edge third portion 711c of the first connecting electrode 71 and the second-edge third portion 721c of the second connecting electrode 72 have a minimum distance d2 therebetween, and d2 is in a range of 10 μm to 50 μm. Further, d2 is in a range of 12 μm to 20 μm, for example, it may be 13 μm, 14 μm, 15 μm, 16 μm, or 17 μm. An excessively small electrode distance d2 may increase the risk of short circuit, posing a threat to the safe operation of the LED. However, an excessively large distance d2 may also lead to non-uniform current distribution, affecting the luminous uniformity and stability of the LED. In addition, it would increase the size and packaging difficulty of the LED, which is detrimental to the trend of LED integration development. Furthermore, the distance between the first-edge third portion 711c of the first connecting electrode 71 and the second-edge third portion 721c of the second connecting electrode 72 remains constant in both the first direction and the second direction.

In a specific embodiment, a connection between the first-edge third portion 711c and the first-edge second portion 711b or the first-edge fourth portion 711d of the first connecting electrode 71 has a first transition segment 712. A connection between the second-edge third portion 721c and the second-edge second portion 721b or the second-edge fourth portion 721d of the second connecting electrode 72 has a second transition segment 722. The first transition segment 712 and the second transition segment 722 have a minimum distance d8 therebetween, and d8>d2. That is, in the first direction, a distance between the first-edge third portion 711c of the first connecting electrode 71 and the second-edge third portion 721c of the second connecting electrode 72 constitutes the minimum distance between the first connecting electrode 71 and the second connecting electrode 72.

With continued reference to FIGS. 4 and 5, a second insulating layer 80 is formed on the semiconductor stacked layer 20 by a method such as PVD or CVD, and is subsequentially patterned by photolithography and etching to create a fourth opening OP4 and a fifth opening OP5, thereby exposing the first connecting electrode 71 and the second connecting electrode 72, respectively. The material selection and structural design of the second insulating layer 80 are similar to those of the first insulating layer 60 and will not be repeated here. In a specific embodiment, a thickness of the second insulating layer 80 is in a range of 500 nm to 1,500 nm.

With continued reference to FIGS. 4 and 5, the first pad electrode 91 and the second pad electrode 92 are formed on the second insulating layer 80 by a method such as electro-plating, PVD, or CVD. A material for the first pad electrode 91 and the second pad electrode 92 may be a single material selected from the group consisting of Au, tin (Sn), Ni, lead (Pb), Ag, indium (In), Cr, germanium (Ge), Si, Ti, W, and Pt, or a single film of an alloy including at least two thereof; or a multi-layer structure including a combination thereof. The first pad electrode 91 is formed inside the fourth opening OP4 and makes contact with the first connecting electrode 71, and the second pad electrode 92 is formed inside the fifth opening OP5 and is electrically connected to the second connecting electrode 72. The first connecting electrode 71 and the first pad electrode 91 are arranged close to the third side E3 of the substrate 10, and the second connecting electrode 72 and the second pad electrode 92 are arranged close to the first side E1 of the substrate 10.

With continued reference to FIGS. 4 and 5, the semiconductor stacked layer 20 includes multiple through-holes 206 extending from the second semiconductor layer 203 through the active layer 202 into portions of the first semiconductor layer 201. A projection of the first pad electrode 91 in the third direction is non-overlapped with a projection of each through-hole 206 in the third direction, and a projection of the second pad electrode 92 in the third direction is non-overlapped with the projection of each through-hole 206 in the third direction. In other words, no N-type holes are present beneath the second pad electrode 92, so that the surfaces of both the first pad electrode 91 and the second pad electrode 92 remain substantially flat. During thermocompression die bonding, this flatness reduces a void ratio at the interface between the LED and the package substrate and prevents uneven stress distribution on surface steps, thereby minimizing the risk of insulating layer rupture and associated short circuit failures.

To reduce the risk of short circuit of the LED caused by the rupture of the second insulating layer 80 connecting metals of different polarities, a projection of each through-hole 206 in the second direction does not overlap with a projection of the first pad electrode 91 in the second direction. Likewise, the projection of each through-hole 206 in the second direction does not overlap with a projection of the second pad electrode 92 in the second direction. In addition, a projection of the first pad electrode 91 in the third direction is located within the projection of the first connecting electrode 71 in the third direction, and a projection of the second pad electrode 92 in the third direction is located within the projection of the second connecting electrode 72 in the third direction. Consequently, areas of the first pad electrode 91 and the second pad electrode 92 are constrained by the areas of the first connecting electrode 71 and the second connecting electrode 72. In particular, the area of the second pad electrode 92 can easily be compressed, leading to a large area difference between the first pad electrode 91 and the second pad electrode, thereby affecting heat dissipation capability and die-shear strength of the LED. In a specific embodiment, a ratio of the area of the second pad electrode 92 to the area of the first pad electrode 91 is in a range of 1.00 to 1.30.

The projection of the second pad electrode 92 in the second direction does not overlap with the projection of the first connecting electrode 71 in the second direction, realizing a P/N electrode separation design. Consequently, there is no first connecting electrode 71 present at the edge and the inner surrounding area of the second pad electrode 92. During thermocompression in a packaging process, even if the insulating layer ruptures or breaks, only regions of the same polarity will come into contact, and the risk of short circuit of P/N electrodes or current leakage of the LED caused by substrate material protrusion or insulating layer rupture during thermocompression is eliminated.

In a specific embodiment, and as shown in FIG. 7, the first pad electrode 91 and the second pad electrode 92 have a minimum distance d1 therebetween, and d1 is in a range of 60 μm to 250 μm. Specifically, d1 is in a range of 80 μm to 140 μm, for example, it may be 90 μm, 100 μm, 110 μm, 120 μm, or 130 μm. An excessively small distance d1 may cause the two pad electrodes to bridge during soldering or operation, leading to an electrical short and impairing normal function of the LED. Conversely, an excessively large distance d2 increases the package footprint and can raise series resistance, affecting current transmission efficiency.

In a specific embodiment, and as shown in FIG. 7, second pad electrode 92 and the first connecting electrode 71 have a minimum distance therebetween d3, and d3 is in a range of 20 μm to 50 μm. Specifically, d3 is in a range of 20 μm to 30 μm. More specifically, the minimum distance d3 is measured at a mid-point of the first-edge third portion 711c of the first connecting electrode 71 to the second pad electrode 92. A minimum distance between an edge of the first-edge third portion 711c and the second pad electrode 92 is defined as d4, and d4≥d3.

In a specific embodiment, and as shown in FIG. 7, the projection of the second connecting electrode 72 in the third direction is located within the projection of the semiconductor mesa 204 in the third direction and has a minimum distance d5 from the first outer sidewall 205a, and d5>d6. This enlarges an area of the first connecting electrode 71 on the N-side, thereby improving current transport transmission performance. It should be understood that a difference between d5 and d6 should be limited within a certain range to avoid excessive area difference between the two electrodes, which may cause current crowding and reduce the overall luminous efficiency of the LED.

In a specific embodiment, and as shown in FIG. 7, the projection of the second connecting electrode 72 in the third direction is located within the projection of the semiconductor mesa 204 in the third direction. The second connecting electrode 72 and the second outer sidewall 205b have a minimum distance d7 therebetween, and d7 is in a range of 0 to 20 μm. Specifically, d7 is measured between the second outer sidewall 205b and a the second-edge first portion 721a, the second-edge second portion 721b, or the second-edge fourth portion 721d of the second connecting electrode 72. Furthermore, d7 is in a range of 0 to 5 μm, thereby maximizing the area of the second connecting electrode 72 and, consequently, the area of the second pad electrode 92, which improves heat dissipation and increases die-shear strength of the LED.

In a specific embodiment, the LED may be polygonal in shape. For example, it may be triangular, hexagonal, rectangular, or square.

As shown in FIG. 8, the embodiment of the disclosure further provides a light-emitting device. The light-emitting device is a flip-chip LED product and includes a package substrate 101 and at least one light-emitting element 102. The at least one light-emitting element 102 is disposed on a surface of the package substrate 101, and the package substrate 101 is electrically connected to an electrode structure of each of the at least one light-emitting element 102. Each of the at least one light-emitting element 102 is the LED provided in the above embodiments of the disclosure. The LED is electrically connected to the package substrate 101 through the first pad electrode 91 and the second pad electrode 92. Owing to a P/N separation design and an absence of the first connecting electrode 71 at the edge and the inner surrounding area of the second pad electrode 92, the light-emitting device prevents occurrence of current leakage of the LED resulting from substrate material protrusion or insulating layer rupture during thermocompression in a packaging process. Therefore, the light-emitting device is particularly suitable for the thermocompression die bonding process, ensuring product quality.

In summary, the LED and the light-emitting device provided by the disclosure effectively overcome various drawbacks in the related art and therefore possess high industrial utilization value.

The above embodiments are merely illustrative descriptions of principles and effects of the disclosure, and are not intended to limit the disclosure. Those skilled in the art may make modifications or changes to the above embodiments without departing from the spirit and scope of the disclosure. Therefore, all equivalent modifications or changes completed by those skilled in the art without departing from the spirit and technical concept disclosed in the disclosure shall still be encompassed by the appended claims of the disclosure.

What is claimed is:

1. A light-emitting diode (LED), comprising:
a substrate, having s first side, a second side, a third side, and a fourth side sequentially connected in that order, wherein the first side is connected to the fourth side, the second side and the fourth side each extends along a first direction, and the first side and the third side each extends along a second direction; and the first direction and the second direction are perpendicular to each other;
a semiconductor stacked layer, disposed on the substrate, wherein the semiconductor stacked layer comprises a first semiconductor layer, a second semiconductor layer, and an active layer disposed between the first semiconductor layer and the second semiconductor layer;
a first connecting electrode and a second connecting electrode, disposed on the semiconductor stacked layer, wherein the first connecting electrode and the second connecting electrode are electrically connected to the first semiconductor layer and the second semiconductor layer, respectively; and
a first pad electrode and a second pad electrode, disposed on the first semiconductor layer and the second semiconductor layer, wherein the first pad electrode and the second pad electrode are electrically connected to the first connecting electrode and the second connecting electrode, respectively;
wherein the first connecting electrode and the first pad electrode are arranged close to the third side of the substrate, and the second connecting electrode and the second pad electrode are arranged close to the first side of the substrate; and
wherein a projection of the second pad electrode in the second direction does not overlap with a projection of the first connecting electrode in the second direction.

2. The LED as claimed in claim 1, wherein the first connecting electrode has a first edge, and the first edge comprises a first-edge first portion facing towards the third side of the substrate, a first-edge second portion facing towards the second side of the substrate, a first-edge third portion facing towards the second connecting electrode, and a first-edge fourth portion facing towards the fourth side of the substrate;
wherein the second connecting electrode has a second edge, and the second edge comprises a second-edge first portion facing towards the first side of the substrate, a second-edge second portion facing towards the second side of the substrate, a second-edge third portion facing towards the first connecting electrode, and a second-edge fourth portion facing towards the fourth side of the substrate; and
wherein a projection of the first-edge third portion in the second direction and a projection of the second-edge third portion in the second direction have an overlapping region.

3. The LED as claimed in claim 2, wherein a projection of the first-edge first portion in the first direction overlaps with a projection of the second-edge first portion in the first direction.

4. The LED as claimed in claim 1, wherein the semiconductor stacked layer further comprises a plurality of through-holes extending from the second semiconductor layer through the active layer into a portion of the first semiconductor layer, a projection of the first pad electrode in a third direction is non-overlapped with a projection of each of the plurality of through-holes in the third direction, and a projection of the second pad electrode in the third direction is non-overlapped with the projection of each of the plurality of through-holes in the third direction; and the third direction is a stacking direction of the semiconductor stack layer.

5. The LED as claimed in claim 4, wherein a projection of each of the plurality of through-holes in the second direction does not overlap with a projection of the first pad electrode in the second direction, and the projection of each of the plurality of through-holes in the second direction does not overlap with a projection of the second pad electrode in the second direction.

6. The LED as claimed in claim 1, wherein the semiconductor stacked layer comprises a peripheral portion and a semiconductor mesa, the peripheral portion extends from the second semiconductor layer through the active layer into a portion of the first semiconductor layer and surrounds the semiconductor mesa, and the peripheral portion has a first outer sidewall connected to the substrate.

7. The LED as claimed in claim 6, wherein the first connecting electrode has an edge close to an edge of the substrate, and a projection of the edge of the first connecting electrode in a third direction is located within a projection of the semiconductor mesa in the third direction.

8. The LED as claimed in claim 6, wherein the first connecting electrode has an edge close to an edge of the substrate, a projection of the edge of the first connecting electrode in a third direction is located within a projection of the peripheral portion in the third direction and has a minimum distance d6 from the first outer sidewall, d6 is in a range of 0 to 20 micrometers (μm).

9. The LED as claimed in claim 8, wherein a projection of the second connecting electrode in the third direction is located within a projection of the semiconductor mesa in the third direction and has a minimum distance d5 from the first outer sidewall, and d5>d6.

10. The LED as claimed in claim 6, wherein a projection of the second connecting electrode in a third direction is located within a projection of the semiconductor mesa in the third direction, the semiconductor mesa comprises a second outer sidewall connected to the peripheral portion, the second connecting electrode and the second outer sidewall have a minimum distance d7 therebetween, and d7 is in a range of 0 to 20 μm.

11. The LED as claimed in claim 2, wherein the first-edge third portion of the first connecting electrode and the second-edge third portion of the second connecting electrode have a minimum distance d2 therebetween, and d2 is in a range of 10 μm to 50 μm.

12. The LED as claimed in claim 11, wherein a connection between the first-edge third portion and the first-edge second portion or the first-edge fourth portion of the first connecting electrode has a first transition segment;
wherein a connection between the second-edge third portion and the second-edge second portion or the second-edge fourth portion of the second connecting electrode has a second transition segment; and
wherein the first transition segment and the second transition segment have a minimum distance d8 therebetween, and d8>d2.

13. The LED as claimed in claim 6, wherein the first pad electrode and the second pad electrode have a minimum distance d1 therebetween, and d1 is in a range of 60 μm to 250 μm.

14. The LED as claimed in claim 6, wherein the second pad electrode and the first connecting electrode have a minimum distance d3 therebetween, and d3 is in a range of 20 μm to 50 μm.

15. The LED as claimed in claim 1, wherein an area of the first connecting electrode is greater than an area of the second connecting electrode.

16. The LED as claimed in claim 1, further comprising a reflective layer disposed on the semiconductor stacked layer, wherein a projection of an outer edge of the reflective layer in a third direction is located with a projection of a semiconductor mesa of the semiconductor stacked layer in the third direction, and four corners of the reflective layer at least have two different chamfered structures configured to identify a polarity direction of the LED.

17. The LED as claimed in claim 1, wherein a current density of the LED is less than 0.6 amperes per square millimeter (A/mm²).

18. A light-emitting device, comprising:
a package substrate; and
at least one LED, disposed on a surface of the package substrate, wherein the package substrate is electrically connected to an electrode structure of each of the at least one LED, and each of the at least one LED is the LED as claimed in claim 1.
